(19) United States
(12) Patent Application Publication
(10) Pub. No.: US 2026/0347170 A1
(43) Pub. Date: Nov. 5, 2026

(54) MEMS SENSOR FOR MEASURING AN ENVIRONMENTAL PARAMETER OF A SENSOR ENVIRONMENT

(71) Applicant: Robert Bosch GmbH, Stuttgart (DE)

(72) Inventors: Heribert Weber, Nuertingen (DE); Thomas Friedrich, Moessingen-Oeschingen (DE)

(21) Appl. No.: 19/385,323

(22) Filed: Nov. 11, 2025

(30) Foreign Application Priority Data
Nov. 21, 2024 (DE) 10 2024 211 184.8

(51) Int. Cl. B81B 3/00

(52) U.S. Cl. CPC B81B 3/0051; B81B 3/0021; B81B 2201/0257; B81B 2201/0264; B81B 2203/0127; B81B 2203/04

(57) ABSTRACT

A MEMS sensor for measuring an environmental parameter of a sensor environment. The MEMS sensor includes: a substrate on which a layer system comprising a plurality of layers, in particular electrically conductive and electrically non-conductive layers, is arranged, the layer system including: a first membrane deflectable in a vertical direction depending on the environmental parameter, a second membrane at a distance in the vertical direction from the first membrane and deflectable in the vertical direction depending on the environmental parameter, a center electrode structure arranged between the first and the second membranes at a distance from them, at least one support structure penetrating the center electrode structure in a freely movable manner and mechanically connecting the first membrane and the second membrane to one another. The center electrode structure is spatially separated, around the contour, from the surrounding layer system.

### FIELD

The present invention relates to a MEMS sensor for measuring an environmental parameter of a sensor environment.

### BACKGROUND INFORMATION

Germany Patent Application No. DE 10 2017 204 023 A1 describes a MEMS device and a MEMS vacuum microphone.

Germany Patent Application No. DE 10 2020 134 171 A1 describes a sound transducer.

Germany Patent Application No. DE 10 2021 133 848 A1 describes a MEMS device with electrodes and a dielectric.

Europe Patent Application No. EP 3 754 325 A1 describes a photoacoustic gas sensor and a pressure sensor.

Germany Patent Application No. DE 10 2015 103 236 A1 describes a MEMS sensor structure for sensing pressure waves and a change in ambient pressure.

Germany Patent Application No. DE 10 2017 212 613 A1 describes a MEMS component and a method for producing a MEMS component.

### SUMMARY

An object of the present invention is to provide a MEMS sensor for measuring an environmental parameter of a sensor environment.

This object may be achieved by means of certain features of the present invention. Advantageous example embodiments of the present invention are disclosed herein.

According to one aspect of the present invention, a MEMS sensor is provided for measuring an environmental parameter of a sensor environment. According to an example embodiment of the present invention, the MEMS sensor includes:
a substrate on which a layer system comprising a plurality of layers, in particular electrically conductive and electrically non-conductive layers, is arranged,
the layer system comprising:
a first membrane that can be deflected in a vertical direction depending on the environmental parameter,
a second membrane arranged at a distance in the vertical direction from the first membrane and deflectable in the vertical direction depending on the environmental parameter,
a center electrode structure which is arranged between the first and the second membranes at a distance from them,
at least one support structure which penetrates the center electrode structure in a freely movable manner and mechanically connects the first membrane and the second membrane to one another, so that a deflection of the first membrane is coupled to a deflection of the second membrane,
wherein the center electrode structure is spatially separated, around the contour, from the surrounding layer system, wherein the center electrode structure is connected, elastically in the direction of its main plane of extension and substantially rigidly in particular perpendicular to its main plane of extension, to at least one adjacent layer of the layer system by one or more elastic elements starting from at least one upper side and a lower side of the center electrode structure.

According to the present invention disclosed herein, it is provided in particular that the center electrode structure is spatially separated, around the contour, from the surrounding layer system, i.e., from layers of the layer system that surround the center electrode structure. Here, around the contour or “surround” relate to a main plane of extension of the center electrode structure.

In the case of a fixed clamping of the center electrode structure as described in the related art, after the removal of sacrificial layers in a cavity region of a MEMS sensor a deflection of the center electrode structure from a central position/zero position can occur due to pressure stress of the center electrode structure and/or due to temperature, which can negatively affect sensor performance.

A flexible design for connecting the center electrode structure to a surrounding layer system by elastic/spring elements within the main plane of extension of the center electrode structure, where the connection consists of the layer system forming the center electrode structure, can have the disadvantage that it also influences/allows/promotes mobility of the center electrode structure in a direction perpendicular to the main plane of extension of the center electrode structure, whereby mechanical vibrations and/or accelerations perpendicular to the main plane of extension of the center electrode structure can lead to an increased deflection of the center electrode structure from a central position, which can influence/impair an ascertained measurement signal to an increased degree.

The disadvantages described above can be efficiently avoided by spatially separating the center electrode structure, around the contour, from the surrounding layer system. Thus, according to an the present invention disclosed herein, the center electrode structure is no longer rigidly clamped in the direction of the main plane of extension, but is connected to or in the surrounding layer system in a manner that allows expansion in the direction of the main plane of extension. It is provided that an electrically conductive and/or electrically non-conductive connection is provided from the upper side of the center electrode structure, aligned parallel to the main plane of extension of the center electrode, and/or from the lower side of the center electrode structure opposite the upper side, to at least one adjacent layer of the layer system, and in particular substantially rigidly perpendicular to its main plane of extension. An electrically non-conductive connection of the center electrode structure to adjacent layers allows a mechanical connection of the center electrode structure while maintaining the electrical separation of the center electrode and the adjacent layers. An electrically conductive connection of the center electrode structure to adjacent layers, at least in some regions, makes it possible to electrically contact the center electrode starting from a sensor surface.

A layer within the meaning of the description is in particular an electrically conductive layer or is in particular an electrically non-conductive layer.

The “upper side” refers to the side of the center electrode structure that is aligned parallel to the main plane of extension of the center electrode structure. The “lower side” refers to the side of the center electrode structure that is aligned parallel to the main plane of extension of the center electrode structure and is opposite the upper side.

Thus, an efficient elastic connection of the center electrode structure in the direction of the main plane of extension, and in particular substantially rigidly perpendicular to its main plane of extension, to or in the layer system can be achieved, which at least partially avoids the disadvantages in the related art, described above, of a flexible/elastic connection within the main plane of extension of a/the center electrode structure to the surrounding layer system.

According to the related art described above, the center electrode structure can generally be connected to the layer system at its edges via flexible or elastic or spring-like elements.

According to an example embodiment of the present invention disclosed herein, however, it is provided that the center electrode structure is connected to at least one adjacent layer of the layer system in a direction perpendicular to its main plane of extension on its upper side and/or on its lower side by one or more elements that are elastically deformable, for example in the direction of the main plane of extension of the center electrode structure.

This results in particular in the technical advantage of providing a MEMS sensor that does not exhibit, or exhibits only to a greatly reduced degree, the disadvantages in the related art described above. In particular, pressure stress and/or temperature-induced deflection of the center electrode structure from a central/zero position due to a fixed clamping in the direction of the main plane of extension of the center electrode, as described above in the related art, can be efficiently avoided.

The wording “at least one” means “one or more.”

This means in particular that, for example, only one or for example a plurality of elements that are elastically deformable, for example in the direction of the main plane of extension of the center electrode structure, may be provided. Explanations made in connection with one element that is elastically deformable, for example in the direction of the main plane of extension of the center electrode structure, apply analogously to a plurality of elements that are elastically deformable, for example in the direction of the main plane of extension of the center electrode structure, and vice versa.

For example, according to an example embodiment of the present invention, it is provided that the center electrode structure is elastically connected to one or more adjacent layers of the layer system by one or more elements that are elastically deformable in the direction of its main plane of extension, starting from the upper side of the center electrode structure.

For example, according to an example embodiment of the present invention, it is provided that the center electrode structure is elastically connected to one or more adjacent layers of the layer system by one or more elements that are elastically deformable in the direction of the main plane of extension of the center electrode structure, starting from the lower side of the center electrode structure.

For example, according to an example embodiment of the present invention, it is provided that the center electrode structure is elastically connected to one or more adjacent layers of the layer system by one or more elements that are elastically deformable in the direction of the main plane of extension of the center electrode structure, starting from the upper side of the center electrode structure and from the lower side of the center electrode structure.

In one example embodiment of the MEMS sensor of the present invention, it is provided that the one or more elastic elements are each configured to allow a change in length of the center electrodes in the direction of their main plane of extension, and to substantially prevent movement of the center electrode structure in a direction perpendicular to the main plane of extension of the center electrode structure.

This results in the technical advantage, for example, of providing an efficient stress decoupling effect.

Stress decoupling of the center electrode structure is achieved here by providing elastically deformable elements, which are provided from the upper and/or lower side of the center electrode structure between the center electrode structure and adjacent layers of the layer system, wherein the elastic elements act in such a way that a change in length/expansion of the center electrode structure is allowed in a main plane of extension of the center electrode structure, but no movement of the center electrode structure in a direction perpendicular to the main plane of extension of the center electrode structure can take place, or at least not substantially. Because the center electrode structure is designed to be separated around the contour from the surrounding layer system, a change in length/expansion can occur in the main plane of extension of the center electrode structure.

The stress decoupling can be visualized as follows: at least in some regions, the center electrode structure is connected to the surrounding layer system in such a way that the elastic elements attached to it act like leaf springs arranged perpendicular to the main plane of extension, allowing, for example, a change in length/expansion in the main plane of extension of the center electrode structure, but not allowing a movement perpendicular thereto. In this way, bending of the center electrode structure due to stress components acting in the main plane of extension of the center electrode structure can advantageously be effectively and efficiently prevented without affecting the mechanical stability of the center electrode structure and/or the central/zero position of the center electrode structure.

Thus, it is provided that, according to this example embodiment of the present invention, the function/effect of the one or more elastic elements correspond to that of a leaf spring.

In one example embodiment of the MEMS sensor of the present invention, it is provided that the center electrode structure is connected to at least one of the layers forming the first membrane and the second membrane by at least one of the one or more elastic elements.

In order to avoid influencing the membrane properties, the elastically deformable elements between the center electrode and a membrane-forming layer are provided or placed, for example, in the edge or clamping or anchoring region of membranes/membrane structures.

This results, for example, in the technical advantage that a center electrode structure can be effectively stress-decoupled from a surrounding layer system without affecting the properties of membranes arranged adjacent to the center electrode structure.

In one example embodiment of the MEMS sensor of the present invention, the layer system further comprises: a first electrode, which is arranged between the first membrane and the center electrode structure at a distance from these, such that a first capacitor structure is formed by the first electrode and the center electrode structure, and a second electrode, which is arranged between the second membrane and the center electrode structure at a distance from these, such that a second capacitor structure is formed by the second electrode and the center electrode structure.

This results, for example, in the technical advantage that in particular a differential capacitor structure is created, so that a differential/difference measurement can be carried out so that an environmental parameter of the sensor environment can be measured efficiently.

For example, according to an example embodiment of the present invention, the first electrode is mechanically connected to the first membrane. For example, the electrode is electrically conductively connected to the first membrane. For example, the second electrode is mechanically connected to the second membrane. For example, the second electrode is electrically conductively connected to the second membrane. A support structure within the meaning of the description is, for example, configured to connect the two membranes mechanically and, in particular, electrically conductively. For example, a support structure within the meaning of the description is configured to electrically insulate the two membranes from each other, so that only a mechanical connection via a support structure is provided. Electrical insulation can be achieved, for example, by using one or more electrical insulating layers in at least one insulation region within a support structure. Thus, for example, it can be provided that a support structure within the meaning of the description has an electrical insulating layer or a plurality of electrical insulating layers and/or an insulation region or a plurality of insulation regions in order to electrically insulate the two membranes from each other.

A layer within the meaning of the description, i.e., a layer of the layer system, can, for example, comprise silicon, for example doped polysilicon. An electrical insulating layer can, for example, comprise SiRiN, which stands for “silicon-rich silicon nitride.”

Thus, for example, the first membrane and/or the second membrane and/or the first electrode and/or the second electrode and/or the center electrode structure, for example the first and/or second center electrode described below, can comprise or be formed from silicon. An example of silicon is doped polysilicon. An electrical insulating layer, which, for example, comes into contact with an etching medium to remove sacrificial layers during the manufacturing process of the MEMS sensor, in order, for example, to make the first membrane and the second membrane and the two electrodes attached to them, for example, freely movable, can, for example, have a high etching resistance to an etching medium that is used. When sacrificial layers consisting of, for example, SiO₂ are removed using liquid or gaseous HF, the electrical insulating layer, for example, has a high etching resistance to HF, for example. Such an electrical insulating layer can, for example, comprise or be formed from SiRiN. A design of the support structure is, for example, such that it consists, in particular substantially, of or comprises a material of the layer or of the layer structure of the first membrane, of the second membrane and/or of the center electrode, wherein the support structure optionally additionally has at least one electrical insulation region consisting of a dielectric layer which is etch-resistant to a sacrificial etching medium.

As part of a manufacturing process, it can therefore be provided that, after the removal of the sacrificial layers, the etching access points for the sacrificial layer etching are closed using a further layer system, and electrical conductor paths are formed in order to electrically contact the first membrane, the second membrane and the center electrode structure. The mechanical coupling of the two membranes advantageously causes the freely movable membranes, which are fastened in particular to at least one anchoring region, to experience a deflection in the same direction and of the same magnitude when a sound pressure hits one of the membranes. The differential capacitor arrangement formed using the two electrodes and the center electrode structure can be detuned in such a way that, for example, the capacitance of the first capacitor structure formed using the first electrode and the center electrode structure is increased, and the capacitance of the second capacitor structure formed using the second electrode and the center electrode structure is decreased, or vice versa.

The production of elastic elements that are for example electrically non-conductive in an anchoring region of the membranes, between those layers forming the two membranes, can be used here for example to position the center electrode structure between the two electrodes or within a/the differential capacitor arrangement. Because the center electrode structure is designed to be separated from the surrounding layer system around the contour, for example by insulating trench structures/trench grooves, it is provided for example that the center electrode structure is connected to the surrounding layer system only, i.e. exclusively, via the elastic element(s) attached to the upper side and/or lower side of the center electrode structure.

In general, it is provided in particular that the center electrode structure is connected to one or more adjacent layers of the layer system only, i.e. exclusively, via the elastic element(s).

In one example embodiment of the MEMS sensor of the present invention, it is provided that the center electrode structure has a first center electrode arranged directly opposite the first electrode and at a distance therefrom in the vertical direction and a second center electrode arranged directly opposite the second electrode and at a distance therefrom in the vertical direction, wherein the first capacitor structure is formed by the first electrode and the first center electrode, and wherein the second capacitor structure is formed by the second electrode and the second center electrode, wherein the first center electrode is mechanically and in some regions electrically conductively and/or electrically non-conductively connected to the layer forming the first membrane by at least one of the one or more elastic elements, and wherein the second center electrode is connected to the layer forming the second membrane mechanically and in some regions electrically conductively and/or electrically non-conductively by at least one of the one or more elastic elements, and wherein the connection of the one or more elastic elements takes place between the center electrode and the adjacent layer forming the first membrane and/or the second membrane, for example in an edge region or in an anchoring region of the membranes.

This results, for example, in the technical advantage that the two capacitor structures, i.e. the first and the second capacitor structure, can be formed efficiently without affecting the membrane properties of the two membranes, the first and the second membrane.

According to an example embodiment of the present invention, in the design of the center electrode structure, for example, it is provided that the first center electrode and the second center electrode are electrically insulated from each other.

This results, for example, in the technical advantage that a differential capacitor structure can be efficiently formed by the two capacitor structures, i.e. the first and the second capacitor structure, due to the electrical insulation of the two center electrodes from each other.

Furthermore, by providing the first and second center electrodes and by forming the first and second capacitor structures, the technical advantage can be achieved that a differential capacitor structure can be formed wherein the two membranes, the first membrane and the second membrane, together with the two electrodes, the first electrode and the second electrode, are connected to each other mechanically and electrically conductively via support structures, for example.

In one example embodiment of the MEMS sensor of the present invention, the first center electrode and the second center electrode are spaced apart from each other by electrically insulating spacers that connect the two center electrodes at least only in some regions, so that the first center electrode and the second center electrode are electrically insulated from each other by the spacers.

According to this embodiment, it is thus provided that the two center electrodes are spaced apart from each other but are not separated by an electrical insulating layer over their entire area, rather are connected to each other only in some regions via electrically non-conductive spacers, which may consist of or comprise SiRiN, for example. The technical advantage here is in particular that parasitic capacitances between the two center electrodes can be significantly reduced, and that circuit design effort can thereby be simplified. Furthermore, the layer structure and manufacturing process of the MEMS sensor can be advantageously simplified by providing the two center electrodes, and the two membranes and optionally also the first and second electrodes can be set to the same electrical potential. Optionally, the substrate, which is for example a silicon substrate, can also be set to this potential, i.e. ground, which in turn makes it possible to deposit or arrange or form the layer for the production of the second membrane directly/immediately on the substrate, at least in some regions, which leads to a further simplification of the layer structure of the layer system and thus of the MEMS sensor.

A substrate within the meaning of the description is, for example, a silicon substrate. A substrate within the meaning of the description is, for example, a silicon wafer.

In one example embodiment of the MEMS sensor of the present invention, it is provided that the center electrode structure is elastically connected to at least one layer of the layer system by at least one of the one or more elastic elements, wherein the at least one layer of the layer system is a layer for producing the first electrode and/or the second electrode.

This results, for example, in the technical advantage that influencing the membrane properties by connecting at least one of the one or more elastic elements to a membrane can be completely avoided, wherein in addition the electrical contacting of the center electrode structure can be realized electrically separately from the first and second membranes and electrically separately from electrodes that are mechanically and optionally also electrically connected to the first and second membranes via the at least one layer of the layer system for the production of the first electrode and/or of the second electrode.

In one example embodiment of the MEMS sensor of the present invention, it is provided that at least one of the one or more elastic elements has a z-shaped or a y-shaped shape.

This results, for example, in the technical advantage that an elastic element can have a particularly suitable shape. Such shapes allow for efficient adjustment of the elasticity of the elastic connection in different (spatial) directions.

In one example embodiment of the MEMS sensor of the present invention, it is provided that the z-shaped or y-shaped shape has a reduced geometric dimension at least in some regions in a corresponding plane parallel and/or perpendicular to the main planes of extension of the center electrode structure.

This results, for example, in the technical advantage that the elasticity of the elastic connection can be adjusted particularly efficiently in different (spatial) directions.

In one example embodiment of the MEMS sensor of the present invention, it is provided that the center electrode structure has a layer whose coefficient of expansion is different from the coefficient of expansion of silicon.

This results, for example, in the technical advantage that warping/bending of the center electrode structure in a direction perpendicular to the main planes of extension can be advantageously avoided or reduced.

The abbreviation “MEMS” stands for “micro-electro-mechanical system.”

For example, exactly one center electrode is provided. This means, for example, that the center electrode structure comprises only a single center electrode.

For example, exactly two center electrodes are provided, the first and the second center electrode. This means, for example, that the center electrode structure comprises, for example, exactly two center electrodes, the first center electrode and the second center electrode.

In one example embodiment of the MEMS sensor of the present invention, it is provided that the MEMS sensor comprises: a channel structure penetrating the two membranes and the two electrodes and penetrating the center electrode structure, in particular the first center electrode and the second center electrode, in a freely movable manner and fluidically coupling a first surrounding region adjacent to the first membrane to a second surrounding region adjacent to the second membrane.

This results in the technical advantage, for example, that an efficient fluidic coupling between the first and the second surrounding region is brought about.

Thus, for example, the technical advantage can be achieved that a fluidic connection/fluid channel is provided via which pressure equalization can take place between a cavity, for example in a sensor substrate, and the environment.

In one example embodiment of the MEMS sensor of the present invention, it is provided that this sensor is a pressure sensor, a microphone, a combination of both, and/or is designed as a MEMS transducer, for example for detecting acceleration.

This results, for example, in the technical advantage that particularly suitable MEMS sensors can be provided.

A support structure within the meaning of the description penetrates in particular the first electrode and the second electrode and penetrates the center electrode structure, i.e. for example the first center electrode and the second center electrode, in a freely movable manner.

The term electrode structure refers to the first electrode and/or the second electrode. The terms “center electrode structure” and “counter-electrode structure” can be used synonymously. A membrane within the meaning of the description is a deformable membrane. The terms “membrane” and “membrane structure” can be used synonymously. If the term “support structure” is used, the plural is always implied, and vice versa. For example, a plurality of support structures are provided. Statements made in connection with one support structure apply analogously to a plurality of support structures, and vice versa.

For example, it is provided that the elastic elements can be provided at least partially around the contour and, for example, in the edge region of the center electrode structure and/or, for example, at least in some regions, or locally, in the edge region of the center electrode structure. For example, any number of elastic elements can be provided. For example, an elastic element can have any shape and/or any geometric dimension.

In one example embodiment of the present invention, the MEMS sensor comprises further support structures by which a region is defined in which the coupled membranes are arranged in a freely movable clamped manner, wherein the further support structures are provided within the anchoring region.

In one example embodiment of the MEMS sensor of the present invention, it is provided that the at least one support structure is arranged outside the anchoring region.

In one example embodiment of the present invention, the MEMS sensor comprises further support structures by which a region is defined in which the coupled membranes are arranged in a freely movable clamped manner, wherein at least one connection region is provided in a cavity formed in the layer system, which connection region has at least one of the one or more elastic elements, wherein the center electrode structure is elastically connected to at least one layer of the layer system by the connection region, wherein the further support structures and the connection region are provided within an anchoring region which surrounds the membranes around the contour, and to which the membranes are connected, and via which the membranes are connected to the substrate.

In one example embodiment of the MEMS sensor of the present invention, it is provided that the at least one support structure is arranged within a region of the layer system in which the coupled membranes are arranged in a freely movable clamped manner.

The embodiments and exemplary embodiments described here can be combined with one another in any way even if this is not explicitly described.

### BRIEF DESCRIPTION OF THE DRAWINGS

The present invention is explained in more detail below using preferred exemplary embodiments.

FIG. 1 shows a first MEMS sensor, according to an example embodiment of the present invention.

FIG. 2 shows exemplary possibilities for connecting the center electrode structure, according to the present invention.

FIG. 3 shows a second MEMS sensor, according to an example embodiment of the present invention.

FIG. 4 shows a third MEMS sensor, according to an example embodiment of the present invention.

FIG. 5 shows a fourth MEMS sensor, according to an example embodiment of the present invention.

FIG. 6 shows a fifth MEMS sensor, according to an example embodiment of the present invention.

FIG. 7 shows a sixth MEMS sensor, according to an example embodiment of the present invention.

FIG. 8 shows a seventh MEMS sensor, according to an example embodiment of the present invention.

FIG. 9 shows an eighth MEMS sensor, according to an example embodiment of the present invention.

FIG. 10 shows a ninth MEMS sensor, according to an example embodiment of the present invention.

FIG. 11 shows a tenth MEMS sensor, according to an example embodiment of the present invention.

FIG. 12 shows an eleventh MEMS sensor, according to an example embodiment of the present invention.

In the following, the same reference signs can be used for identical features.

Furthermore, the figures show cross-sectional views.

### DETAILED DESCRIPTION OF EXAMPLE EMBODIMENTS

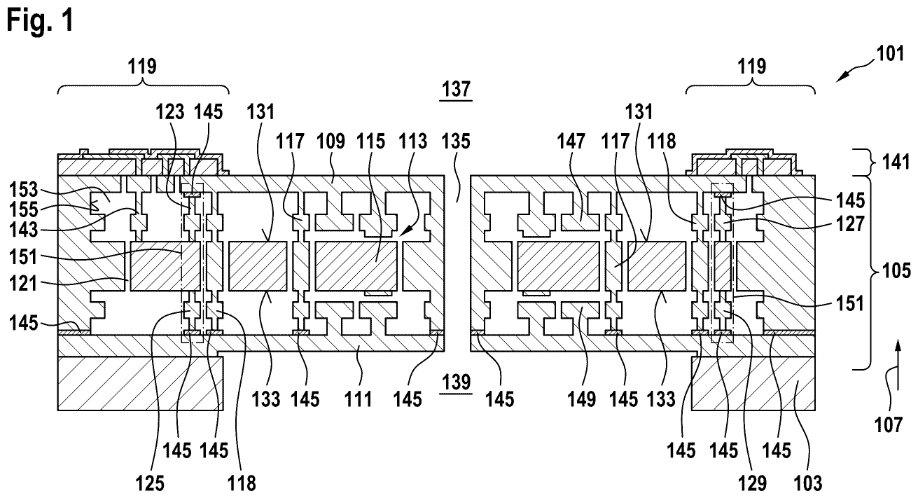

FIG. 1 shows a first MEMS sensor 101 for measuring an environmental parameter of a sensor environment.

The first MEMS sensor 101 comprises a substrate 103, for example a silicon substrate or e.g. a silicon wafer. A layer system 105 is arranged on the substrate 103 and comprises a plurality of layers, in particular electrically conductive and electrically non-conductive layers, which are introduced below.

The layer system 105 comprises a first membrane 109 which can be deflected in a vertical direction, identified by an arrow with the reference sign 107, depending on the environmental parameter. The layer system 105 comprises as a further layer a second membrane 111 which is arranged at a distance from the first membrane 109 in the vertical direction 107 and which can be deflected in the vertical direction 107 depending on the environmental parameter.

The layer system 105 comprises as a further layer or layer structure a center electrode structure 113, which comprises a single center electrode 115, wherein the center electrode structure 113, i.e. the center electrode 115, is arranged between the first membrane 109 and the second membrane 111 at a distance from these.

A plurality of support structures 117 are provided which penetrate the center electrode structure 113 in a freely movable manner and connect the first membrane 109 and the second membrane 107 mechanically and electrically conductively and/or electrically non-conductively to one another, so that a deflection of the first membrane 109 is coupled with a deflection of the second membrane 111, wherein the center electrode structure 113 is spatially separated from the surrounding layer system 105 in its main plane of extension. This is achieved by an insulation trench 121. This means that this insulation trench 121 completely surrounds the center electrode structure 113 in its main plane of extension, defines/determines an outer contour of the center electrode structure 113 in the main plane of extension of the center electrode structure 113, and causes a separation of the center electrode structure 113 in its main plane of extension from the surrounding layer system 105.

Furthermore, further support structures can be used to define a region in which the coupled membranes 109, 111 are arranged in a freely movable clamped manner. The further support structures defining a movable region of the membranes 109, 111 are designated with reference sign 118. The further support structures 118 can, for example, be provided within an anchoring region 119 that surrounds the membranes around the contour, to which the membranes 109, 111 are attached, via which the membranes 109, 111 are connected to the substrate 103 and which laterally delimits a cavity region in a plane perpendicular to a vertical direction 107. The support structures 117, 118 connecting the layers of the two membranes 109, 111 can have the same geometric shape and the same geometric dimensions, or the same geometric shape and different geometric dimensions, or can all have different shapes and different dimensions, or can have different shapes and different dimensions in at least some regions, and can be present in any number in each case.

A plurality of elastic elements 123, 125, 127, 129 are provided which connect the center electrode structure 113 to the layers forming the membranes 109, 111 in such a way that an (elastic) deflection or movement of the center electrode structure 113 is allowed, in particular exclusively or in particular substantially, in its main plane of extension.

The center electrode structure 113 has in the vertical direction 107 an upper side 131 and a lower side 133 opposite the upper side 131.

The first elastic element 123 elastically connects the center electrode structure 113 from the upper side 131 to the layer forming the first membrane 109. The second elastic element 125 elastically connects the center electrode structure 113 from the lower side 133 to the layer forming the second membrane 111. The third elastic element 127 connects the center electrode structure 113 from its upper side 131 to the layer forming the first membrane 109. The fourth elastic element 129 connects the center electrode structure 113 from its lower side 133 to the layer forming the second membrane 111.

Thus, the center electrode structure 113 is elastically connected, from the upper side 131 or the lower side 133, to adjacent layers, here the layer forming the first membrane 109 and the layer forming the second membrane 111 of the layer system 105, via at least these elastic elements 123, 125, 127, 129.

A fluid channel 135 runs through the layer system 105, which channel creates a fluid connection between a first environment 137 of the first membrane 109 and a second environment 139 of the second membrane 111. Thus, for example, pressure equalization can be achieved between these two environments 137, 139.

Reference sign 141 designates a further layer system which is used for electrical contacting of the individual layers of layer system 105, for example with an evaluation circuit, and is optionally used for closing at least one etching access which is used to remove sacrificial layer material from a cavity region between the first and second membranes.

The reference sign 143 indicates, by way of example, an electrical contacting structure within the layer system 105 consisting of electrically conductive layers of the layer system, via which the center electrode structure 113, i.e. the center electrode 115, can be electrically conductively connected to the further layer system 141.

The reference sign 145 indicates electrical insulating layers, for example SiRiN layers. These dielectric layers 145 provide electrical insulation between two layers, which are mechanically connected to each other by the at least one corresponding insulating layer 145. The at least one electrical insulating layer 145 can be provided over the entire surface and/or at least in some regions/locally. Connections through support structures 117, 118 between the membranes 109, 111 or between the layers forming the membranes 109, 111 and/or connections between a center electrode structure 113 and a membrane or a layer forming a membrane through elastic elements 123, 125, 127, 129, can be made electrically non-conductive by providing at least one electrical insulating layer 145 in the region of/within support structures 117, 118 and/or in the region of/within elastic elements 123, 125, 127, 129.

Thus, FIG. 1 shows an exemplary embodiment of a MEMS sensor 101. There are two movable membranes, the first membrane 109 and the second membrane 111, the center electrode 115 and, between the center electrode 115 and the respective membrane 109, 111, a first electrode 147 and a second electrode 149. The first electrode 147 is arranged between the first membrane 109 and the center electrode structure 113 at a distance from these, so that a first capacitor structure is formed by the first electrode 147 and the center electrode structure 113. The second electrode 149 is located between the second membrane 111 and the center electrode structure 113 and is arranged at a distance from these, so that a second capacitor structure is formed by the second electrode 149 and the center electrode structure 113.

The first electrode 147 is advantageously connected to the first membrane 109 via at least one support structure 117, mechanically and optionally also electrically conductively. The second electrode 149 is advantageously connected to the second membrane 111 via at least one support structure 117, mechanically and optionally also electrically conductively.

Furthermore, the two membranes 109, 111, or the layers forming the membranes 109, 111, are connected to each other by support structures 117 or by further support structures 118 respectively, wherein the support structures 117 penetrate the center electrode structure 113 in a freely movable manner, and the further support structures 118 penetrate the center electrode structure in a manner electrically separated from the surrounding center electrode structure 113 by an insulating trench. The support Structures 117, 118 can connect the membranes 109, 111, or the layer forming the membranes 109, 111, to one another mechanically and electrically conductively, or, by inserting at least one electrical insulating layer 145, only mechanically, i.e. in the latter case in an electrically non-conductive manner.

The membranes 109, 111, the first electrode 147 and the second electrode 149 and the center electrode 115 comprise or consist of, for example, silicon, for example doped polysilicon. The electrical insulating layer 145, which can, for example, come into contact with an etching medium for removing sacrificial layers in the course of a manufacturing process of the MEMS sensor 101, in order, for example, to make the membranes 109, 111 and the electrodes 147, 149 attached to them freely movable, has for example a high etching resistance to an etching medium used. When removing sacrificial layers consisting of for example SiO₂ using liquid or gaseous HF, it can be provided for example that the electrical insulating layer 145 has for example a high etch resistance to HF, such as SiRiN (silicon-rich silicon nitride). The structure of the support structures 117 and of the further support structures 118 is designed in particular in such a way that it substantially consists of the material of the layer or the layer structure of the first membrane 109, the second membrane 111 and/or the center electrode 115, and can optionally have electrical insulating regions consisting of at least one electrical insulating layer 145, wherein such an electrical insulating layer can for example comprise SiRiN or be formed from it.

After the removal of the sacrificial layers, the etching accesses for the sacrificial layer etching in the cavity region between the membranes 109, 111 are closed and electrical conductor paths are formed, for example using a further layer system, the further layer system 141, to electrically contact the membranes 109, 111 and the center electrode 115. The mechanical coupling of the membranes 109, 111 causes the freely movable membranes 109, 111, which are attached to at least one anchoring region 119, to experience a deflection in the same direction and of the same magnitude when a sound pressure impinges on a membrane 109, 111. The differential capacitor arrangement formed using the electrodes 147, 149 and the center electrode 115 is detuned for example in such a way that for example the capacitance of the capacitor structure formed using the first electrode 147 and the center electrode 115, the first capacitor structure, is increased and the capacitance of the capacitor structure formed using the second electrode 149 and the center electrode 115, the second capacitor structure, is decreased, or vice versa.

The production of elastic elements 123, 125, 127, 129 between the layers forming the two membranes 109, 111 can also be used for example to position the center electrode 115 between the electrodes 147, 149. If the center electrode 115 is also separated from the surrounding layer system 105 by an insulating trench 121 around the contour in its main plane of extension, then the center electrode 115 is connected to the surrounding layer system 105 only via the elastic elements 123, 125, 127, 129. FIG. 1 shows by way of example how the center electrode 115 is elastically connected and fixed to the layer forming the first membrane 109 and to the layer forming the second membrane 111 by the elastic elements 123, 125, 127, 129. However, the center electrode 115 can also be fixed only to the layer forming the first membrane 109, or only to the layer forming the second membrane 111, or partially to the layer forming the first membrane 109 and/or partially to the layer forming the second membrane 111.

In order to avoid unwanted electrical connections between structures forming capacitors, it is provided for example to provide at least one electrical insulating layer, the electrical insulating layers 145, consisting for example of SiRiN, in the region of or within a support structure 117 or a further support structure 118 or an elastic element 123, 125, 127, 129.

By providing elements that deflect elastically, for example exclusively or for example substantially, in the direction of the main plane of extension, such as the elastic elements 123, 125, 127, 129, it can advantageously be achieved that when the MEMS sensor 101 is accelerated perpendicular to the main plane of extension of the center electrode structure 113, the center electrode 115 is not deflected perpendicular to its main plane of extension in the region of the elastic suspension, but can Still readily expand within the main plane of extension.

In this case, the main plane of extension is horizontal, i.e. relative to the vertical direction 107, at a 90° angle thereto, or perpendicular to the vertical direction 107.

The center electrode 115 is shown hatched in FIG. 1. The center electrode 115 is connected here via electrically insulated elastic elements, for example the elastic elements 123, 125, 127, 129, to the layers which are provided for the production of the first membrane 109 and the second membrane 111. The elastic elements 123, 125, 127, 129 can here for example consist of the material forming the membranes 109, 111, the two electrodes 147, 149 and/or the center electrode 115, for example polysilicon. For example, the polysilicon can be further doped to exhibit good electrical conductivity. The elastic elements 123, 125, 127, 129 fixing the center electrode 115 are here made electrically insulating with respect to the two membranes 109, 111 by the provision of electrical insulating layers 145 and can be arranged locally, for example in the region of the at least one anchoring region 119 and here between those further support structures 118 defining a deflectable center region of a membrane 109, 111 and the wall, formed by the layer system of the anchoring region 119, of a cavity region provided between the membranes 109, 111, and/or can be arranged between further support structures 118 arranged adjacent/opposite one another and defining a deflectable region of a membrane 109, 111.

Reference sign 151 indicates a connection region of the center electrode structure 113 to the layers forming the membranes 109, 111. This means that, for example, the elastic elements 123, 125, 127, 129 are positioned within the region 151. For example, the region 151 is located within an anchoring region 119 of the membranes 109, 111.

The at least one electrical contacting structure 143, which electrically conductively connects the center electrode 115 to electrical conductor paths within the further layer system 141, is arranged for example in a region which is located on a side of elastic elements 123, 125, 127, 129, and/or of further support structures 118 within a cavity 153, which side faces away from a center region of the membrane composite comprising the first and second membranes.

In order to form the at least one electrically conductive connection between at least one conductor path of the further layer system 141 and the center electrode 115, the at least one electrical contacting structure 143 is provided in such a way that it penetrates a layer forming the first membrane 109 in an electrically insulated manner. In this case, an electrically insulated sub-region within the layer forming the first membrane 109 can be a part/component of the contacting structure 143.

Alternatively or additionally, at least one elastic element 123, 125, 127, 129 can be provided/designed in such a way that an electrical contacting between conductor paths in the additional layer 141 and the center electrode 115 can be achieved/made/implemented via this at least one elastic element 123, 125, 127, 129.

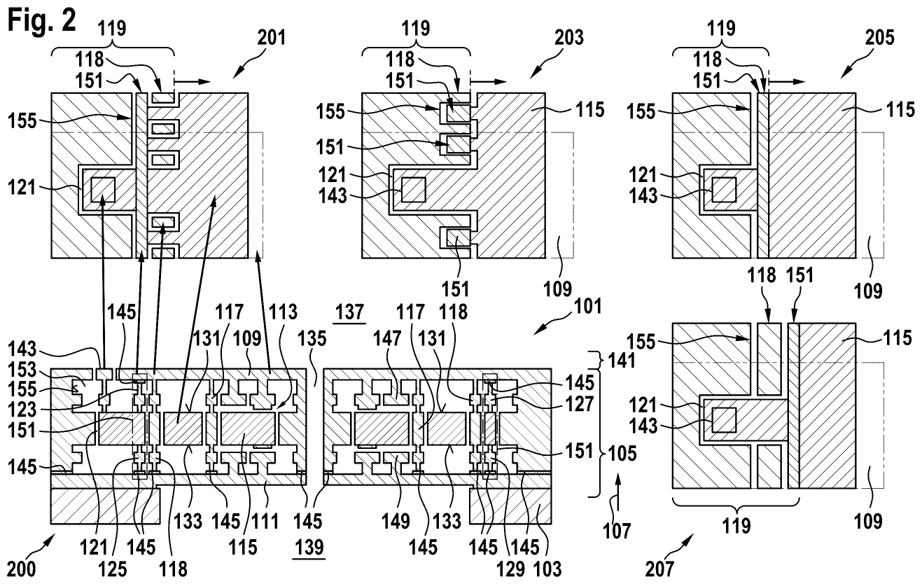

FIG. 2 shows exemplary possibilities for connecting the center electrode structure 113 to the membranes 109, 111.

The reference sign 153 indicates a cavity 153 formed by the two membranes 109, 111. The reference sign 155 indicates an inner wall of a cavity.

As FIG. 2 shows by way of example, the anchoring region 119 of the membranes 109, 111 can be interrupted at least in some regions, for example in order to be able to realize an electrical contacting and/or mechanical fixing of the center electrode 115 within the anchoring region 119 on a side facing away from the center region of the membranes 109, 111 and further support structures 118 that define a deflection region of the membranes 109, 111.

In detail, FIG. 2 shows a simplified cross-sectional view 200 of the first MEMS sensor 101 of FIG. 1, wherein for the sake of clarity the further layer system 141 is not shown.

The other four drawings are corresponding top views of the first MEMS sensor 101 relating to examples of different possibilities for realizing the anchoring of the membranes 109, 111 or the elastic connection of the center electrode 115. These different possibilities are illustrated by four top views: a first top view 201, a second top view 203, a third top view 205 and a fourth top view 207.

According to the first top view 201, the connection region 151 is, for example, continuous at least in some regions and is formed between further support structures 118, which are arranged at least locally and define a deflection region of the membrane composite comprising the first and second membranes 109, 111, and a cavity wall 155, electrically insulated from these, wherein at least sub-regions of the center electrode structure 113 comprising a single center electrode 115 are routed through between the further support structures 118 in an electrically insulated manner and are connected to the connection region 151 at least in some regions.

According to the second top view 203, the connection region 151 is for example interrupted in some regions such that, for example, between adjacent structures forming or defining the connection region 151, further support structures 118 defining a deflection region of the membrane composite of the first and second membranes 109, 111 are provided, which support structures are for example connected to the cavity wall 155 at least in some regions mechanically and electrically conductively or electrically non-conductively and/or are for example realized at least in some regions at a distance from the cavity wall 155.

According to the third top view 205, the connection region 151 is for example continuous, wherein the connection region 151 and the further support structure 118, made as a single structure, form a single, common structure which defines a deflection region of the membrane composite of the first and second membranes 109, 111 and to which the center electrode structure 113, for example comprising a single center electrode 115, is connected.

According to the fourth top view 207, the connection region 151 is, for example, continuous at least in some regions, with a further support structure 118 being provided between the connection region 151 and the cavity wall 155 at least in some regions at a distance from this, i.e. at a distance from the connection region 151.

In all the aforementioned exemplary embodiments, an electrical contacting structure 143 for the electrical contacting of the center electrode structure 113, in this case in particular the single center electrode 115, can be provided on a side of the connection region 151 facing away from a center region of the two membranes 109, 111.

According to FIG. 1, the membranes 109, 111 are mechanically coupled, but electrically separated from each other due to the insulating layers 145. The polysilicon layer forming the second membrane 111 by way of example can, for example, be arranged directly on the substrate 103, at least in some regions, outside the freely movable membrane region. Optionally, for example, at least one further electrical insulating layer can however also be provided outside the freely movable membrane region, between the layer forming the second membrane 111, for example the polysilicon layer, and the substrate 103. This at least one further electrical insulating layer and also, for example, layers provided for electrical insulation in the further layer system 141 but not shown in FIG. 1 can for example consist of SiO₂, SiRiN, Si₃N₄ and/or oxide nitride, or can comprise such materials.

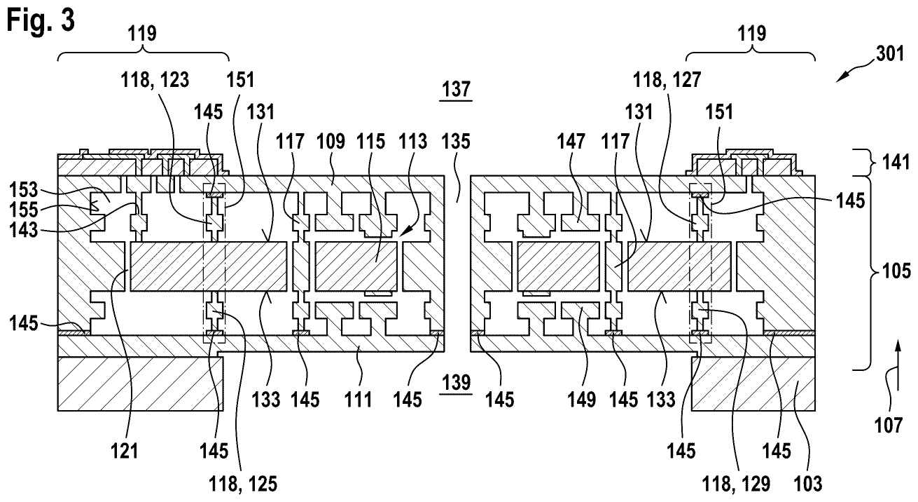

FIG. 3 shows a second MEMS sensor 301 for measuring an environmental parameter of a sensor environment. In the second MEMS sensor 301, the connection region 151 of the center electrode structure 113 simultaneously serves to define the deflectable region of the membranes 109, 111. In this exemplary embodiment, the connection region 151 of the center electrode structure 113 provided within the anchoring region 119 and simultaneously defines the deflectable region of the membranes 109, 111 does not necessarily have to coincide with or be connected to the wall 155, which is formed between the layers forming the two membranes 109, 111, of the cavity 153 formed between the membranes 109, 111. Rather, it can also be located, for example, at a distance from a cavity wall 155 created between the layers forming the membranes 109, 111, i.e. the inner wall 155 of the cavity 153, within the cavity region, i.e. inside the cavity 153, and can be provided adjacent to/outside the deflectable region of the membranes 109, 111. In order to allow the center electrode 115 to extend as unhindered as possible in the main plane of extension, it may be provided, for example, to also construct the structure making electrical contact with the center electrode 115, the structure with reference sign 143, within the sensor structure, for example within the anchoring region 119, like a structure fixing the center electrode structure 113, i.e. like one of the elastic elements 123, 125, 127, 129, and to provide this within the cavity region formed between the membranes 109, 111 or the formed cavity 153 between an electrically insulated region within at least one of the layer forming the membrane 109, 111 and the center electrode structure 113.

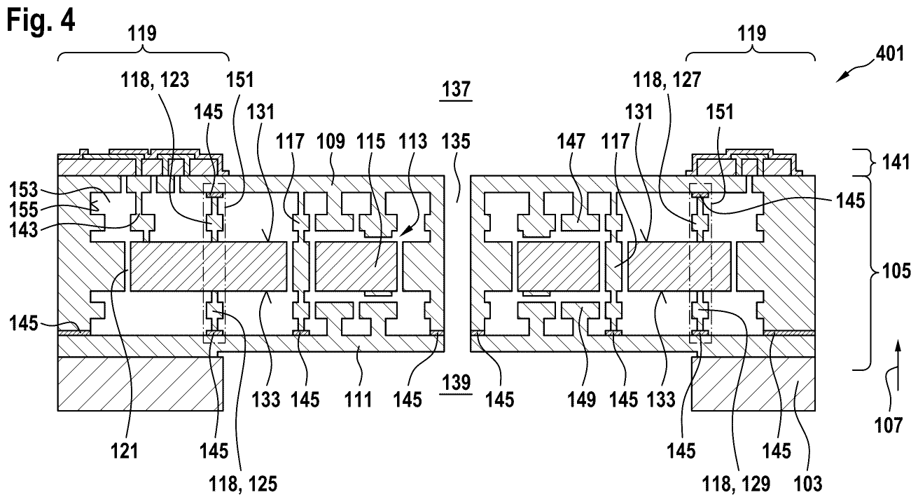

While the electrical contacting of the center electrode 115 in the exemplary embodiments according to FIGS. 1 and 3 is carried out using a structure designed in a straight line perpendicular to the main plane of extension of the center electrode structure 113, the electrical contacting can also be carried out by a more flexible, more mobile, for example z-shaped structure, as is shown in a third MEMS sensor 401 according to FIG. 4.

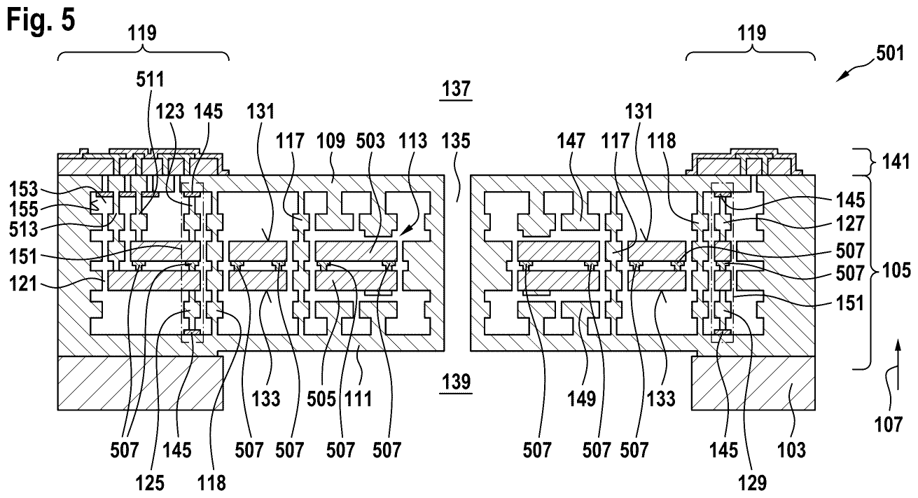

FIG. 5 shows a fourth MEMS sensor 501 for measuring an environmental parameter of a sensor environment.

According to the fourth MEMS sensor 501, the center electrode structure 113 comprises a first center electrode 503 and a second center electrode 505. The first center electrode 503 is located e.g. directly opposite the first electrode 147, and is arranged at a distance from it in the vertical direction 107. The second center electrode 105 is arranged e.g. directly opposite the first center electrode 503 and at a distance from it in the vertical direction 107. The second center electrode 505 is arranged e.g. directly opposite the second electrode 149 and at a distance from it in the vertical direction 107.

A plurality of spacers 507 are provided, wherein these are provided for example only in some regions, and connect the two center electrodes 503, 505 mechanically and electrically non-conductively, so that the first center electrode 503 and the second center electrode 505 are electrically insulated from each other by the spacers 507. Alternatively, the spacers 507 can also be electrically conductive and the electrically conductively connected first and second center electrodes 503, 507 can form a center electrode structure 113, the single center electrode 115 of which consists of sub-regions that are spaced apart from one another and are electrically conductively connected.

Alternatively or additionally, for example, a material or layer can be used to manufacture the spacers 507 in order to reduce or avoid, at least within the deflection region of the membranes 109, 111, a bending/deflection of the center electrode structure 113 in a vertical direction 107.

Thus, FIG. 5 shows a center electrode structure 113 consisting of two center electrodes that are mechanically connected to each other but electrically insulated from one another: the first center electrode 503 and the second center electrode 505. The center electrodes 503, 505 are here not connected to each other over their entire surface by an electrical insulating layer, but rather are mechanically connected to one another so as to be electrically insulated only in some regions, via the spacers 507. The spacers 507 comprise or consist, for example, of SiRiN. A particular advantage here is that the absence of a planar/large-area insulating layer mechanically connecting the first and second center electrodes 503, 505 can significantly reduce parasitic capacitances between the center electrodes 503, 505, thereby simplifying circuit design effort. Furthermore, by providing the two center electrodes 503, 505, the layer structure and the manufacturing process of the MEMS sensor 501 can be simplified, and the membranes 109, 111 and optionally also the electrodes 147, 149, which are electrically conductively connected to the membranes 109, 111 via support structures 117, can be set to the same potential. Optionally, the substrate 103 can also be set to this potential, for example ground, which in turn advantageously makes it possible to deposit the layer for the production of the second membrane 111 directly/immediately on the substrate 103, at least in some regions, for example outside a movably designed region of the membrane composite of the mechanically and optionally electrically conductively coupled first and second membranes 109, 111, which leads to a further simplification of the layer structure of the MEMS sensor 501. Analogously to the explanations for FIGS. 1 and 2, the two center electrodes 503, 505 can here as well e.g. again be elastically connected or fixed at least in some regions to the layer for producing the first membrane 109 and/or at least in some regions to the layer for producing the second membrane 111 via electrically insulated elastic elements 123, 125, 127, 129.

Specifically, for example, the first elastic element 123 connects the first center electrode 503 to the layer forming the first membrane 109. The second element 125 connects the second center electrode 505 to the layer forming the second membrane 111. The third elastic element 127 connects the first center electrode 503 to the layer forming the first membrane 109. The fourth elastic element 129 connects the second center electrode 505 to the layer forming the second membrane 111.

By specifically introduced insulation trench structures, for example the at least one insulation trench 121, the center electrodes 503, 505 can be separated from the surrounding layer system 105 in their main plane of extension in order to allow them to expand in their main plane of extension. As described above, electrical contacting structures can also be provided here through or with the help of the layer system 105 within the cavity in order to electrically connect electrical conductor paths or conductor path structures within the further layer system 141 to the center electrodes 503, 505.

As shown and described in FIG. 3, it can also be provided here to fix the two center electrodes 503, 505 directly to at least one of the layers forming the membranes 109, 111 within the anchoring region 119 mechanically and electrically non-conductively, as is shown by way of example in FIG. 5.

The reference sign 511 indicates an electrical contacting of the first center electrode 503. The reference sign 513 indicates an electrical contacting of the second electrode 505.

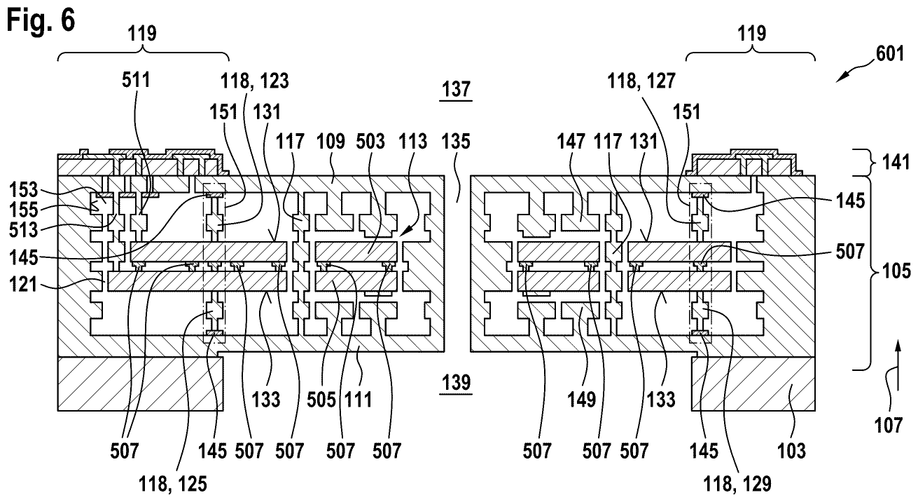

FIG. 6 shows a fifth MEMS sensor 601 for measuring an environmental parameter of a sensor environment.

One difference between the fifth MEMS sensor 601 of FIG. 6 and the fourth MEMS sensor 501 of FIG. 5 is for example that at least some of the support structures 118 defining a deflection region of the membranes 109, 111 can be used to elastically connect the center electrodes 503, 505 mechanically and electrically non-conductively to at least one of the layers forming the membrane 109, 111. In relation to a center point of the membrane composite, these elastic connections or elements, for example the elastic elements 123, 125, 127, 129, have the same distance to the center point as the support structures 118 in the anchoring region 119, which define a deflection region of the membranes 109, 111 or of the membrane composite and penetrate the center electrodes 503, 505 “in a freely movable manner” or penetrate the center electrodes 503, 505 in an electrically insulated manner.

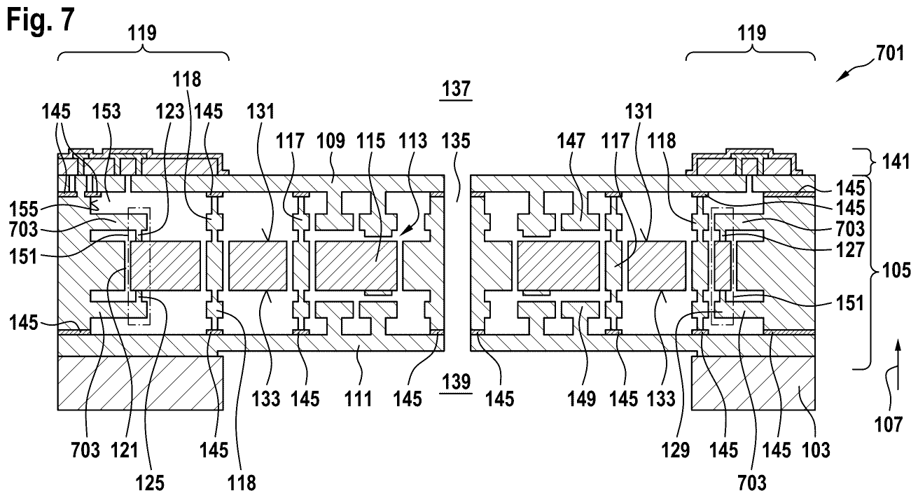

FIG. 7 shows a sixth MEMS sensor 701 for measuring an environmental parameter of a sensor environment.

In the sixth MEMS sensor 701, in contrast to the exemplary embodiments described in FIG. 1 to 6, in which the fixing of the center electrode(s) to the layers for the production of the two membranes 109, 111 was fixed or elastically connected, it is provided for the center electrode structure 113 to be connected to the relevant layer for the production of the first electrode 147 and/or to the layer for the production of the second electrode 149 using the elastic elements 123, 125, 127, 129 in such a way that, for example, (exclusively) the center electrode structure 113 is elastically connected substantially in the direction of the main plane of extension. FIG. 7 shows by way of example that the center electrode 115 is attached or elastically connected via the elastic elements 123, 125, 127, 129 to structures which consist of the layer for the production of the first electrode 147 and/or of the layer for the production of the second electrode 149 and which can project from the wall 155 of the cavity 153 into the cavity 153 in an anchoring region 119 between the layers forming the membranes 109, 111 and at a distance from the layers forming the membranes 109, 111, and which can, for example, be electrically insulated from the layers forming the membranes 109, 111 and/or from the electrodes 147, 149.

These structures projecting from the wall 155 of the cavity 153 into the cavity 153 are marked with reference sign 703.

Here too, the provision of an insulation trench 121 running around the center electrode structure 113 again allows (unhindered) expansion of the center electrode 115 in the main plane of extension. The electrical contacting of the center electrode 115 or the center electrodes 503, 505 can be achieved by structures 703, which are correspondingly made electrically insulated within the layer system 105 and which project from the wall 155 of the cavity 153 into the cavity 153, and the correspondingly provided elastic elements 123, 125, 127, 129.

The flexibility of an elastic element within the meaning of the description for the elastic connection of the center electrode structure can, for example, be achieved accordingly via a structural and/or geometric and/or material design of the elastic element. In addition, for example, the number and/or position of the elastic elements for the elastic connection can be determined according to the requirements. Furthermore, for example, the center electrode structure can have one or more layers that have a different coefficient of expansion compared to silicon.

In FIG. 1 to 7, the elastic elements 123, 125, 127, 129 have a straight-line shape in the vertical direction 107, or perpendicular to the main plane of extension of the center electrode structure 113. As described and shown in the following figures, the flexibility of the elastic connection can be influenced by a structural and/or geometric design.

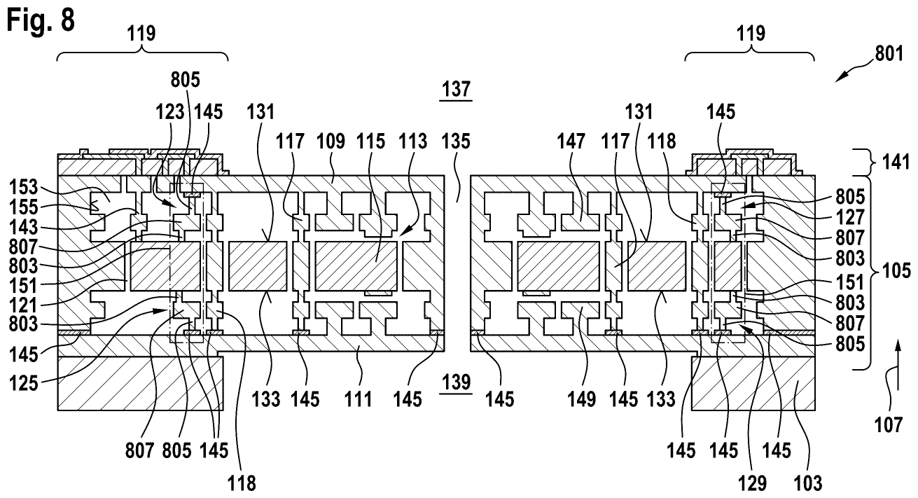

FIG. 8 shows a seventh MEMS sensor 801 for measuring an environmental parameter of a sensor environment.

Elastic elements are shown here in FIG. 8, as used for example in the embodiment according to FIG. 4 for the electrical contacting of the center electrode 115. Therefore, the elastic elements 123, 125, 127, 129 have a z-shaped shape. For example, it may be provided that the elastic elements 123, 125, 127, 129 consist of or comprise a material of the first electrode 147 and/or the second electrode 149 and/or the center electrode 115 and/or the layer forming the first membrane 109 and/or the layer forming the second membrane 111 and/or the material of an insulating layer 145, and/or are formed at least partially/in some regions from the layers of the layer structure 105, wherein sub-regions 803, 805 of each of the elastic elements 123, 125, 127, 129 are connected to the center electrode 115 and to a layer forming a membrane 109, 111 in such a way that their central perpendiculars running in the vertical direction 107 are not congruent, and wherein the sub-regions 803, 805 are connected to one another by a connecting element 807.

The elastic elements 123, 125, 127, 129 thus each comprise at least two sub-regions 803, 805 with non-congruent central perpendiculars and a connecting element 807 connecting the two sub-regions 803, 805. The sub-regions 803, 805 and/or the connecting elements 807, consisting for example of a material of the first electrode 147 and/or the second electrode 149 and/or the center electrode 115 and/or the layer forming the first membrane 109 and/or the layer forming the second membrane 111 and/or the material of an insulating layer 145 and/or are formed at least partially/in some regions from the layers of the layer structure 105. The sub-regions 803, 805 can also be referred to as support elements.

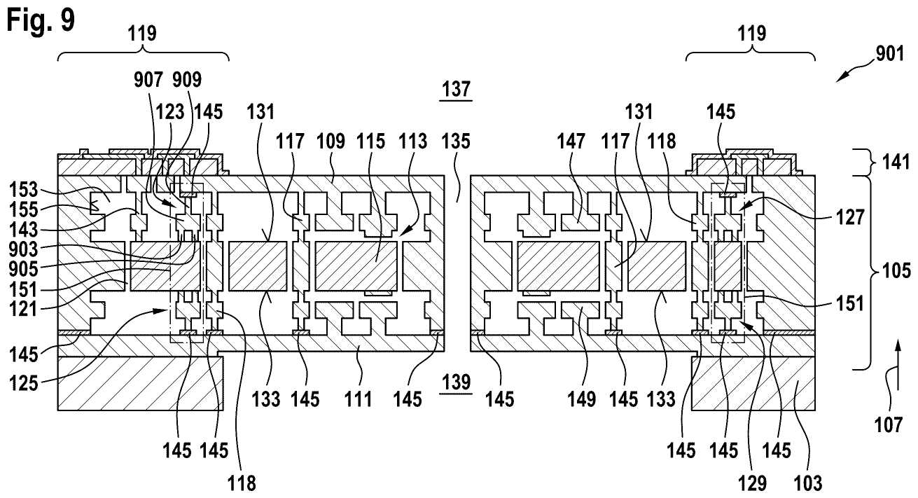

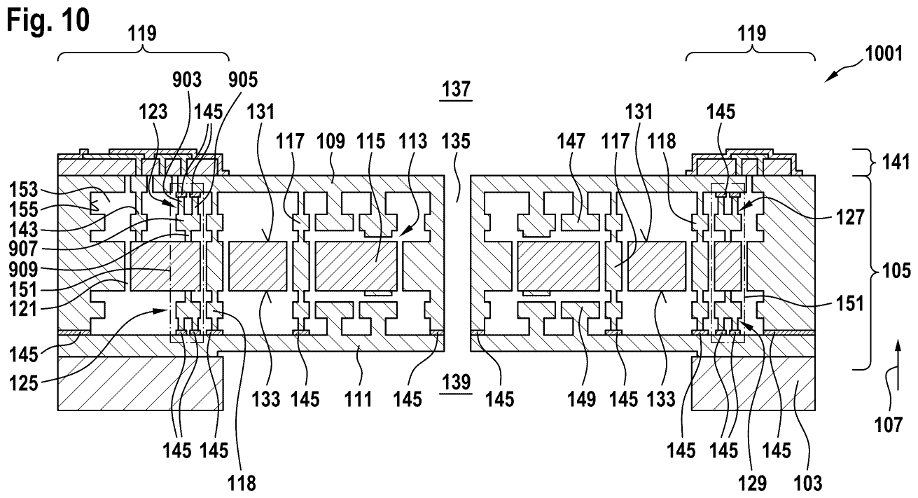

FIG. 9 shows an eighth MEMS sensor 901 for measuring an environmental parameter of a sensor environment. FIG. 10 shows a ninth MEMS sensor 1001 for measuring an environmental parameter of a sensor environment.

The two MEMS sensors 901 and 1001 of FIGS. 9 and 10 show exemplary elastic elements 123, 125, 127, 129 which have a y-shaped shape. The elastic elements 123, 125, 127, 129 have, for example, at least two support elements 903, 905, for example arranged directly adjacent to one another, a connecting element 907, which mechanically and electrically conductively or electrically non-conductively connects the two support elements 903, 905, and a support element 909, which is mechanically and electrically conductively or electrically non-conductively connected to the support element on the side of the connecting element 907 opposite the two support elements 903, 905. For example, it is provided that the two support elements 903, 905 are also connected to the connecting element 907 in an electrically conductive or electrically non-conductive manner. The two support elements 903, 905 are located between the connecting element 907 and the center electrode structure 113, and the support element 909 is located between the connecting element 907 and the corresponding layer forming a first membrane 109 or a second membrane 111, in such a manner that a central perpendicular of the support element 909 extending in the vertical direction 107 is not formed/arranged congruent with a central perpendicular of the support element 903 and/or of the support element 905 aligned in the vertical direction, and the central perpendicular of the support element 909 is located, for example, between the central perpendiculars of the support elements 903, 905, as shown in FIG. 9. Alternatively, the two support elements 903, 905 can be provided between the connecting element 907 and the corresponding layer forming a first membrane 109 or a second membrane 111, and the support element 909 can be provided between the connecting element 907 and the center electrode structure 113 and arranged in such a way that a central perpendicular of the support element 909 extending in the vertical direction 107 is not congruent with a central perpendicular of the support element 903 and/or the support element 905 aligned in the vertical direction, and the central perpendicular of the support element 909 is located, for example, between the central perpendiculars of the support elements 903, 905, as in the ninth MEMS sensor 1001 shown in FIG. 10 for measuring an environmental parameter of a sensor environment.

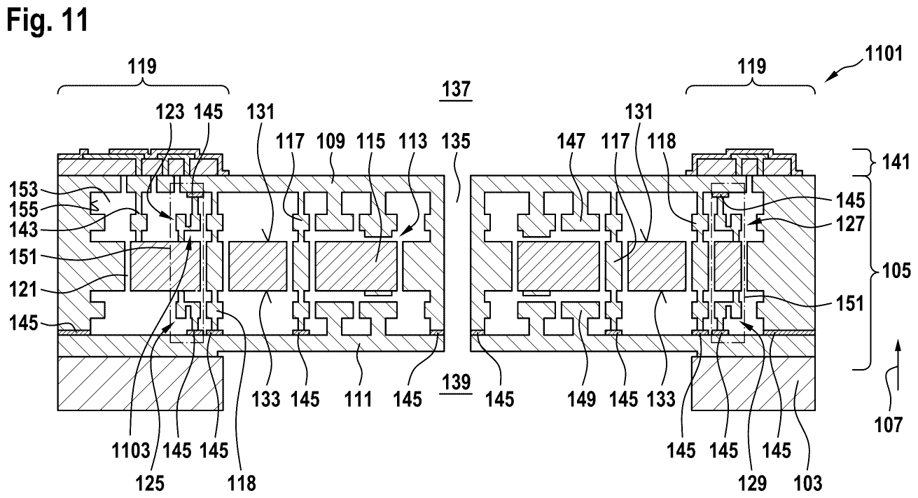

FIG. 11 shows a tenth MEMS sensor 1101 for measuring an environmental parameter of a sensor environment.

In detail, the tenth MEMS sensor 1101 is a variant of the seventh MEMS sensor 801 of FIG. 8, insofar as the elastic elements 123, 125, 127, 129 have a connecting element which has a layer thickness reduced locally/in some regions in the direction of the vertical direction and/or optionally has a structure width reduced locally/in some regions parallel to the main plane of extension of the center electrode 115. This connecting element is designated by reference sign 1103.

This principle can, for example, also be applied to the variants of the elastic elements 123, 125, 127, 129 shown in FIGS. 9 and 10, such that, for example, a smaller layer thickness and/or optionally a smaller structure width of the connecting element 907 can be provided at least in some regions between two adjacent support elements 903, 905.

In this respect, the figures described above show, for example, elastic elements whose z-shaped or y-shaped shape in a plane parallel and/or perpendicular to the main plane of extension of the center electrode structure 113 can have a reduced geometric dimension at least in some regions.

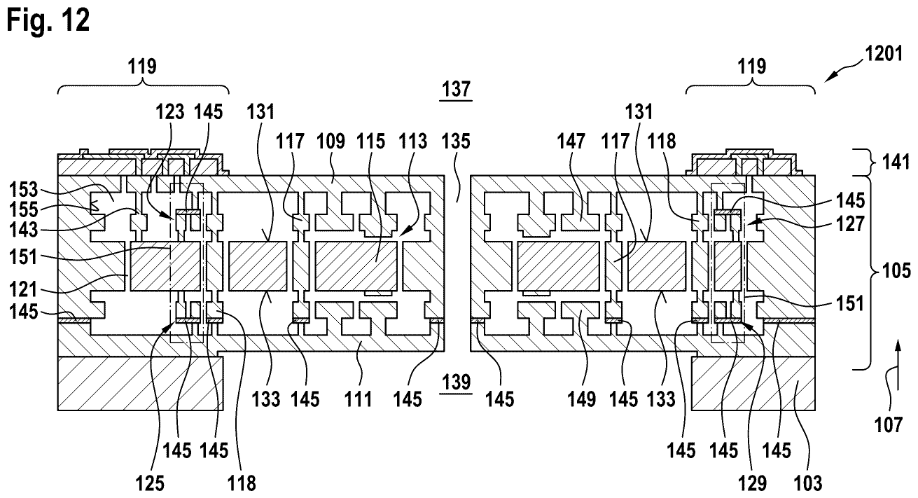

FIG. 12 shows an eleventh MEMS sensor 1201 for measuring an environmental parameter of a sensor environment. The elements 123, 125, 127, 129 shown in FIG. 12 differ from the elastic connecting elements 123, 125, 127, 129 according to FIG. 8 in that the support elements or central perpendiculars are not connected to each other via a connecting element made of a material of at least one of the electrodes 147, 149. The connecting element connecting the support elements can, for example, consist of or comprise a material that is used for the electrical insulation of electrical components within the layer system 105 and/or the cavity region or the cavity 153, such as SiRiN. Thus, an electrical insulating layer 145 can be provided as a connecting element between the two support elements.

This concept can also be applied, for example, to the variants shown in FIGS. 9 and 10, such that the support elements 903, 905 are connected via a connecting element 907, which, unlike the material for the electrodes 147, 149, consists of for example SiRiN or comprises such a material. The use of SiRiN as a material for one of these connecting elements has the further advantage that the elastic elements can also be made electrically non-conductive through/via the connecting element. Alternatively, differing from the material for the electrodes 147, 149, and/or instead of SiRiN, a different electrically insulating or electrically conductive material may be used, wherein this material for example should have a high etching resistance to an etching medium used to remove sacrificial layers from a cavity region.

In general, and independently of the exemplary embodiments shown in the figures, it is provided for example that the support structures and/or the further support structures are each designed to be electrically conductive or electrically non-conductive.

In general and independently of the exemplary embodiments shown in the figures, it is provided, for example, that the further support structures 118 are provided within an anchoring region 119 which surrounds the membranes 109, 111 around the contour, to which the membranes 109, 111 are attached, via which the membranes 109, 111 are connected to the substrate 103 and which laterally delimits a cavity region or a cavity 153 in a plane perpendicular to a vertical direction 107. Furthermore, for example, further support structures 118, which define a deflection region of a first and a second membrane 109, 111, and for example a connection region 151, by which a center electrode structure 113 is fastened, can be designed in such a way, that, for example, further support structures 118 are located between a connection region 151 and a cavity wall 155 or, for example, further support structures 118 are located between the connection region 151 and the cavity wall 155 and/or, for example, regions of a connection region 151 are located at least partially between adjacently arranged further support structures 118 and/or, for example, the center electrode structure 113 extends at least partially around support structures 118 at a distance from further support structures 118 and/or, for example, a further support structure 118 and/or a connection region 151 is made in one piece or, for example, is formed from a plurality of sub-regions, wherein, for example, support structures 118 can optionally be connected to a cavity wall 155 in an electrically conductive or electrically non-conductive manner at least in some regions/partially.

The further support structures 118 and/or the connection region 151 are, for example, at least partially or in some regions formed from the material of the layers of the layer system 105 and/or, for example, at least partially or in some regions formed from layers of the layer system 105 itself.

1-14. (canceled)

15. A MEMS sensor for measuring an environmental parameter of a sensor environment, the MEMS sensor comprising:
a substrate on which a layer system including a plurality of electrically conductive and electrically non-conductive layers, is arranged, the layer system including:
a first membrane that can be deflected in a vertical direction depending on the environmental parameter,
a second membrane arranged at a distance in the vertical direction from the first membrane and deflectable in the vertical direction depending on the environmental parameter,
a center electrode structure which is arranged between the first membrane and the second membrane, at a distance from the first membrane and the second membrane,
at least one support structure which penetrates the center electrode structure in a freely movable manner, the support structure mechanically connecting the first membrane and the second membrane to one another so that a deflection of the first membrane is coupled to a deflection of the second membrane,
wherein the center electrode structure is spatially separated, around a contour, from surrounding portion of the layer system,
wherein the center electrode structure is connected, elastically in a direction of a main plane of extension of the center electrode structure and substantially rigidly perpendicular to the main plane of extension of the center electrode structure, to at least one adjacent layer of the layer system by one or more elastic elements starting from at least one upper side of the center electrode structure and a lower side of the center electrode structure.

16. The MEMS sensor according to claim 15, wherein the one or more elastic elements are each configured to allow a change in length of the center electrode structure and/or center electrodes of the center electrode structure in a direction of main planes of extension of the center electrode structure and/or the center electrodes, and to substantially prevent movement of the center electrode structure and/or the center electrodes in a direction perpendicular to the main planes of extension of the center electrode structure and/or the center electrodes.

17. The MEMS sensor according to claim 15, wherein at least one elastic connection formed by the one or more elastic elements includes at least one electrically insulating layer such that the at least one adjacent layer and the center electrode structure are electrically insulated from each other via the at least one elastic connection.

18. The MEMS sensor according to claim 15, wherein the center electrode structure is connected to at least one layer forming the first membrane and a layer forming the second membrane by at least one of the one or more elastic elements.

19. The MEMS sensor according to claim 15, wherein the layer system further includes:
a first electrode which is arranged between the first membrane and the center electrode structure at a distance from the first membrane and the center electrode structure, such that a first capacitor structure is formed by the first electrode and the center electrode structure, and
a second electrode which is arranged between the second membrane and the center electrode structure at a distance from the second membrane and the center electrode structure, so that a second capacitor structure is formed by the second electrode and the center electrode structure.

20. The MEMS sensor according to claim 19, wherein the center electrode structure includes a first center electrode arranged directly opposite the first electrode and at a distance from the first electrode in the vertical direction, and a second center electrode arranged directly opposite the second electrode and at a distance from the second electrode in the vertical direction, wherein the first capacitor structure is formed by the first electrode and the first center electrode, and wherein the second capacitor structure is formed by the second electrode and the second center electrode, wherein the first center electrode is elastically connected to a layer forming the first membrane by at least one of the one or more elastic elements, and wherein the second center electrode is elastically connected to a layer forming the second membrane by at least one of the one or more elastic elements.

21. The MEMS sensor according to claim 19, wherein the first center electrode and the second center electrode are arranged spaced apart from each other by spacers that are electrically insulating and/or electrically conductive, and that connect the first center electrode and the second center electrode at least in some regions, such that the first center electrode and the second center electrode are connected to each other in electrically conductive fashion or in electrically insulating fashion by the spacers.

22. The MEMS sensor according to claim 19, wherein the center electrode structure is elastically connected to at least one layer of the layer system by at least one of the one or more elastic elements, wherein the at least one layer of the layer system is a layer for producing the first electrode and/or the second electrode.

23. The MEMS sensor according to claim 19, wherein at least one of the one or more elastic elements has a z-shaped or a y-shaped shape.

24. The MEMS sensor according to claim 23, wherein the z-shaped shape or the y-shaped shape has a reduced geometric dimension at least in some regions in a plane parallel and/or perpendicular to main planes of extension of the center electrode structure.

25. The MEMS sensor according to claim 15, wherein the center electrode structure has a layer whose coefficient of expansion is different from a coefficient of expansion of silicon.

26. The MEMS sensor according to claim 15, further comprising further support structures by which a region is defined on which the first and the second membranes are arranged in a freely movable clamped manner, wherein at least one connection region is provided in a cavity formed in the layer system, the at least one connection region having at least one of the one or more elastic elements, wherein the center electrode structure is elastically connected to at least one layer of the layer system by the connection region, wherein the further support structures and the at least one connection region are provided within an anchoring region which surrounds the first and the second membranes around the contour, and to which the first and the second membranes are connected, and via which the first and the second membranes are connected to the substrate.

27. The MEMS sensor according to claim 15, wherein the at least one support structure is arranged within a region of the layer system in which the coupled membranes are arranged in a freely movable clamped manner.

28. The MEMS sensor according to claim 15, wherein the MEMS sensor is a pressure sensor and/or a microphone and/or a MEMS transducer.
